(19) United States
(12) Patent Application Publication
(10) Pub. No.: US 2026/0350244 A1
(43) Pub. Date: Nov. 5, 2026

(54) GENERATIVE OBJECT DESIGN SYSTEM

(71) Applicant: GM Global Technology Operations LLC, Detroit, MI (US)

(72) Inventors: Alok Warey, Novi, MI (US); Rajan R. Chakravarty, Troy, MI (US); Dong Yeon Yoo, Lake Orion, MI (US); Corden Minor, Center Line, MI (US)

(73) Assignee: GM Global Technology Operations LLC, Detroit, MI (US)

(21) Appl. No.: 19/196,425

(22) Filed: May 1, 2025

(51) Int. Cl. G06F 30/12

(52) U.S. Cl. CPC G06F 30/12

(57) ABSTRACT

A computer-implemented method when executed by data processing hardware causes the data processing hardware to perform operations. The operations include providing, at a diffusion model of a generative object design algorithm, training data, the training data including a plurality of stored three-dimensional (3D) objects and a plurality of stored object slices, generating, based on the training data, a two-dimensional (2D) object image via the diffusion model, predicting, via an attention residual U-Net model of the generative object design algorithm, 2D object slices of the generated 2D object image, and combining the predicted object slices via the generative object design algorithm into a 3D object design.

### INTRODUCTION

The information provided in this section is for the purpose of generally presenting the context of the disclosure. Work of the presently named inventors, to the extent it is described in this section, as well as aspects of the description that may not otherwise qualify as prior art at the time of filing, are neither expressly nor impliedly admitted as prior art against the present disclosure.

The present disclosure relates generally to a generative three-dimensional (3D) object design system.

The design and development of vehicle objects, such as wheels, is a complex and time-consuming process that often involves multiple iterative steps. Designers typically spend a significant amount of time refining their concepts through numerous iterations to achieve the desired aesthetic and functional characteristics. This extensive process can limit the number of designs that can be developed within a given timeframe, thereby restricting the variety and innovation in object designs available in the market.

Once the initial two-dimensional designs are finalized, the designs must be translated into three-dimensional models to assess their feasibility and to prepare for manufacturing. However, the current methods for creating these three-dimensional models from two-dimensional sketches or designs are often inefficient and result in outputs that lack the necessary precision. This further extends the development timeline and can lead to additional revisions and refinements, thereby increasing the overall effort to bring new object designs to the market. Thus, there is a need for an improved process for developing three-dimensional object designs from two-dimensional sketches or images.

### SUMMARY

In some aspects, a computer-implemented method when executed by data processing hardware causes the data processing hardware to perform operations. The operations include providing, at a diffusion model of a generative object design algorithm, training data, the training data including a plurality of stored three-dimensional (3D) objects and a plurality of stored object slices, generating, based on the training data, a two-dimensional (2D) object image via the diffusion model, predicting, via an attention residual U-Net model of the generative object design algorithm, 2D object slices of the generated 2D object image, and combining the predicted object slices via the generative object design algorithm into a 3D object design.

Optionally, the operations may also include generating, via the generative object design algorithm, a 3D object component and extrapolating the 3D object design from the generated 3D object component. In some examples, providing the training data may include tuning the diffusion model based on the training data, the diffusion model being a machine learning model. In some instances, predicting the 2D object slices includes generating at least twelve object slices. The operations may also include importing via the generative object design algorithm, grid points based on the predicted 2D object slices into a pre-processor of the data processing hardware. Optionally, combining the predicted 2D object slices may include refining the imported grid points. The operations may further include extruding bottom grid points along each predicted 2D object slice via the generative object design algorithm. In some instances, the operations may include meshing the 3D object design. The operations may also include executing a structural and modal analysis on the meshed 3D object design.

In other aspects, a generative three-dimensional (3D) design system includes data processing hardware and memory hardware in communication with the data processing hardware. The memory hardware stores instructions that when executed on the data processing hardware cause the data processing hardware to perform operations. The operations include providing, at a diffusion model of a generative object design algorithm, training data, the training data including a plurality of stored three-dimensional (3D) objects and a plurality of stored object slices, generating, based on the training data, a two-dimensional (2D) object image via the diffusion model, predicting, via an attention residual U-Net model of the generative object design algorithm, object slices of the generated 2D object image, and combining the predicted object slices via the generative object design algorithm into a 3D object design.

In some examples, the stored 3D objects may include wheel rims. Optionally, providing the training data may include tuning the diffusion model based on the training data, the diffusion model being a machine learning model. In some instances, predicting the 2D object slices may include generating at least twelve object slices. The operations may also include extruding bottom grid points along each predicted 2D object slice via the generative object design algorithm. The operations may further include meshing the 3D object design. Optionally, the operations may include executing a structural and modal analysis on the meshed 3D object design.

In further aspects, a generative three-dimensional (3D) design system includes data processing hardware and memory hardware in communication with the data processing hardware. The memory hardware stores instructions that when executed on the data processing hardware cause the data processing hardware to perform operations. The operations include providing, at a diffusion model of a generative object design algorithm, training data, the training data including a plurality of stored three-dimensional (3D) objects and a plurality of stored object slices, generating, based on the training data, a two-dimensional (2D) object image via the diffusion model, and predicting, via an attention residual U-Net model of the generative object design algorithm, object slices of the generated 2D object image. The operations also include importing via the generative object design algorithm, grid points based on the predicted 2D object slices into a pre-processor of the data processing hardware, combining the predicted object slices via the generative object design algorithm into a 3D object design, meshing the 3D object design, and executing a structural and modal analysis on the meshed 3D object design.

In some examples, the operations may include generating, via the generative object design algorithm, a 3D object component and extrapolating the 3D object design from the generated 3D object component.

### BRIEF DESCRIPTION OF THE DRAWINGS

The drawings described herein are for illustrative purposes only of selected configurations and are not intended to limit the scope of the present disclosure.

FIG. 1 is a schematic diagram of a generative three-dimensional (3D) object design system according to the present disclosure;

FIG. 2 is an exemplary block diagram of a generative object design system according to the present disclosure;

FIG. 3 is a schematic diagram of a diffusion model of a generative object design system according to the present disclosure, the diffusion model generating a plurality of two-dimensional object images;

FIG. 4 is a schematic diagram of object slices of a two-dimensional object according to the present disclosure;

FIG. 5 is a schematic diagram of a training database for a generative object design system according to the present disclosure;

FIG. 6 is a schematic diagram illustrating a generative object design system utilizing object slices to generate a three-dimensional object;

FIG. 7 is a schematic diagram of a plurality of grid points and a mesh function of a generative object design system according to the present disclosure;

FIG. 8 is a meshed three-dimensional object according to the present disclosure;

FIG. 9 is an example of a diffusion model according to the present disclosure generating a two-dimensional object;

FIG. 10 is an example of an attention residual U-net model according to the present disclosure generating a plurality of object slices;

FIG. 11 is an example of a diffusion model according to the present disclosure generating a portion of a two-dimensional object;

FIG. 12 is an example of an attention residual U-net model according to the present disclosure generating a plurality of object slices;

FIG. 13 is an example of the plurality of object slices of FIG. 11 being utilized by a generative object design algorithm to generate a three-dimensional object; and

FIG. 14 is an exemplary method of operation of a generative object design system according to the present disclosure.

Corresponding reference numerals indicate corresponding parts throughout the drawings.

### DETAILED DESCRIPTION

Example configurations will now be described more fully with reference to the accompanying drawings. Example configurations are provided so that this disclosure will be thorough, and will fully convey the scope of the disclosure to those of ordinary skill in the art. Specific details are set forth such as examples of specific components, devices, and methods, to provide a thorough understanding of configurations of the present disclosure. It will be apparent to those of ordinary skill in the art that specific details need not be employed, that example configurations may be embodied in many different forms, and that the specific details and the example configurations should not be construed to limit the scope of the disclosure.

The terminology used herein is for the purpose of describing particular exemplary configurations only and is not intended to be limiting. As used herein, the singular articles “a,” “an,” and “the” may be intended to include the plural forms as well, unless the context clearly indicates otherwise. The terms “comprises,” “comprising,” “including,” and “having,” are inclusive and therefore specify the presence of features, steps, operations, elements, and/or components, but do not preclude the presence or addition of one or more other features, steps, operations, elements, components, and/or groups thereof. The method steps, processes, and operations described herein are not to be construed as necessarily requiring their performance in the particular order discussed or illustrated, unless specifically identified as an order of performance. Additional or alternative steps may be employed.

When an element or layer is referred to as being “on,” “engaged to,” “connected to,” “attached to,” or “coupled to” another element or layer, it may be directly on, engaged, connected, attached, or coupled to the other element or layer, or intervening elements or layers may be present. In contrast, when an element is referred to as being “directly on,” “directly engaged to,” “directly connected to,” “directly attached to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

The terms “first,” “second,” “third,” etc. may be used herein to describe various elements, components, regions, layers and/or sections. These elements, components, regions, layers and/or sections should not be limited by these terms. These terms may be only used to distinguish one element, component, region, layer or section from another region, layer or section. Terms such as “first,” “second,” and other numerical terms do not imply a sequence or order unless clearly indicated by the context. Thus, a first element, component, region, layer or section discussed below could be termed a second element, component, region, layer or section without departing from the teachings of the example configurations.

In this application, including the definitions below, the term “module” may be replaced with the term “circuit.” The term “module” may refer to, be part of, or include an Application Specific Integrated Circuit (ASIC); a digital, analog, or mixed analog/digital discrete circuit; a digital, analog, or mixed analog/digital integrated circuit; a combinational logic circuit; a field programmable gate array (FPGA); a processor (shared, dedicated, or group) that executes code; memory (shared, dedicated, or group) that stores code executed by a processor; other suitable hardware components that provide the described functionality; or a combination of some or all of the above, such as in a system-on-chip.

The term “code,” as used above, may include software, firmware, and/or microcode, and may refer to programs, routines, functions, classes, and/or objects. The term “shared processor” encompasses a single processor that executes some or all code from multiple modules. The term “group processor” encompasses a processor that, in combination with additional processors, executes some or all code from one or more modules. The term “shared memory” encompasses a single memory that stores some or all code from multiple modules. The term “group memory” encompasses a memory that, in combination with additional memories, stores some or all code from one or more modules. The term “memory” may be a subset of the term “computer-readable medium.” The term “computer-readable medium” does not encompass transitory electrical and electromagnetic signals propagating through a medium, and may therefore be considered tangible and non-transitory memory. Non-limiting examples of a non-transitory memory include a tangible computer readable medium including a nonvolatile memory, magnetic storage, and optical storage.

The apparatuses and methods described in this application may be partially or fully implemented by one or more computer programs executed by one or more processors. The computer programs include processor-executable instructions that are stored on at least one non-transitory tangible computer readable medium. The computer programs may also include and/or rely on stored data.

A software application (i.e., a software resource) may refer to computer software that causes a computing device to perform a task. In some examples, a software application may be referred to as an “application,” an “app,” or a “program.” Example applications include, but are not limited to, system diagnostic applications, system management applications, system maintenance applications, word processing applications, spreadsheet applications, messaging applications, media streaming applications, social networking applications, and gaming applications.

The non-transitory memory may be physical devices used to store programs (e.g., sequences of instructions) or data (e.g., program state information) on a temporary or permanent basis for use by a computing device. The non-transitory memory may be volatile and/or non-volatile addressable semiconductor memory. Examples of non-volatile memory include, but are not limited to, flash memory and read-only memory (ROM)/programmable read-only memory (PROM)/erasable programmable read-only memory (EPROM)/electronically erasable programmable read-only memory (EEPROM) (e.g., typically used for firmware, such as boot programs). Examples of volatile memory include, but are not limited to, random access memory (RAM), dynamic random access memory (DRAM), static random access memory (SRAM), phase change memory (PCM) as well as disks or tapes.

These computer programs (also known as programs, software, software applications or code) include machine instructions for a programmable processor, and can be implemented in a high-level procedural and/or object-oriented programming language, and/or in assembly/machine language. As used herein, the terms “machine-readable medium” and “computer-readable medium” refer to any computer program product, non-transitory computer readable medium, apparatus and/or device (e.g., magnetic discs, optical disks, memory, Programmable Logic Devices (PLDs)) used to provide machine instructions and/or data to a programmable processor, including a machine-readable medium that receives machine instructions as a machine-readable signal. The term “machine-readable signal” refers to any signal used to provide machine instructions and/or data to a programmable processor.

Various implementations of the systems and techniques described herein can be realized in digital electronic and/or optical circuitry, integrated circuitry, specially designed ASICs (application specific integrated circuits), computer hardware, firmware, software, and/or combinations thereof. These various implementations can include implementation in one or more computer programs that are executable and/or interpretable on a programmable system including at least one programmable processor, which may be special or general purpose, coupled to receive data and instructions from, and to transmit data and instructions to, a storage system, at least one input device, and at least one output device.

The processes and logic flows described in this specification can be performed by one or more programmable processors, also referred to as data processing hardware, executing one or more computer programs to perform functions by operating on input data and generating output. The processes and logic flows can also be performed by special purpose logic circuitry, e.g., an FPGA (field programmable gate array) or an ASIC (application specific integrated circuit). Processors suitable for the execution of a computer program include, by way of example, both general and special purpose microprocessors, and any one or more processors of any kind of digital computer. Generally, a processor will receive instructions and data from a read only memory or a random access memory or both. The essential elements of a computer are a processor for performing instructions and one or more memory devices for storing instructions and data. Generally, a computer will also include, or be operatively coupled to receive data from or transfer data to, or both, one or more mass storage devices for storing data, e.g., magnetic, magneto optical disks, or optical disks. However, a computer need not have such devices. Computer readable media suitable for storing computer program instructions and data include all forms of non-volatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks. The processor and the memory can be supplemented by, or incorporated in, special purpose logic circuitry.

To provide for interaction with a user, one or more aspects of the disclosure can be implemented on a computer having a display device, e.g., a CRT (cathode ray tube), LCD (liquid crystal display) monitor, or touch screen for displaying information to the user and optionally a keyboard and a pointing device, e.g., a mouse or a trackball, by which the user can provide input to the computer. Other kinds of devices can be used to provide interaction with a user as well; for example, feedback provided to the user can be any form of sensory feedback, e.g., visual feedback, auditory feedback, or tactile feedback; and input from the user can be received in any form, including acoustic, speech, or tactile input. In addition, a computer can interact with a user by sending documents to and receiving documents from a device that is used by the user; for example, by sending web pages to a web browser on a user's client device in response to requests received from the web browser.

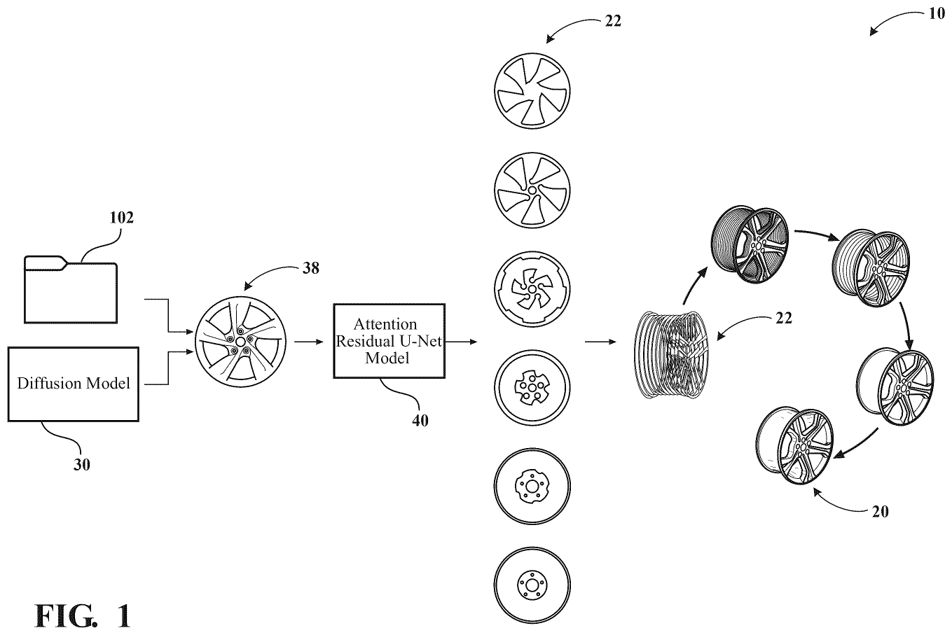

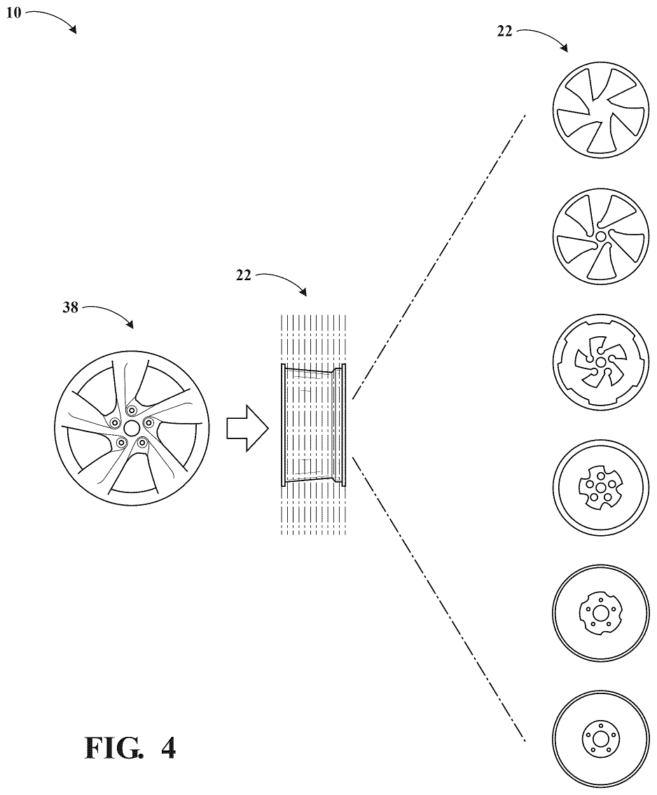

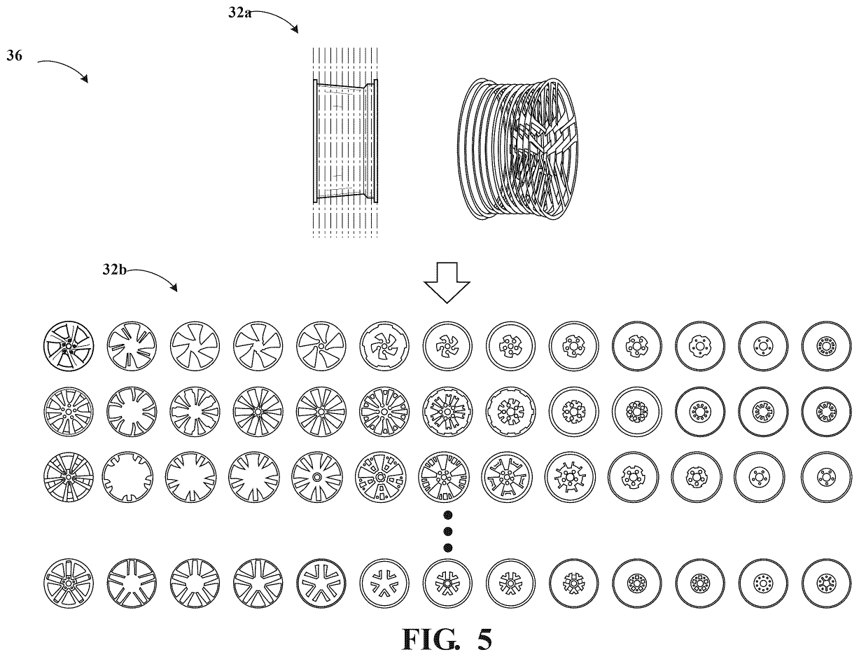

Referring to FIGS. 1-5, a generative object three-dimensional (3D) design system 10 is a computer-implemented system including a controller 12 that executes a generative object design algorithm 14. For example, the generative object design system 10 may be configured as a web-based application having an interactive user interface 100. Users may utilize the interactive user interface 100 to import or otherwise upload images 102. For example, users may drag and drop or manually upload the images 102 through the interactive user interface 100. The generative object design system 10 automatically resizes the images 102 to a standard format for consistent processing and prediction, as described herein.

The generative object design algorithm 14 is executed by data processing hardware 16 of the controller 12. The controller 12 may be a computer or other processor that is configured with data processing hardware 16. The controller 12 also includes memory hardware 18 that is in communication with the data processing hardware 16. The memory hardware 18 stores instructions that, when executed by the data processing hardware 16, cause the data processing hardware 16 to perform operations, described herein. The generative object design algorithm 14 is configured to generate three-dimensional (3D) object models 20 based on predicted two-dimensional (2D) object slices 22, described in more detail below. Users may store the predicted 2D object slices 22 in the memory hardware 18 and/or may utilize the predicted 2D object slices 22 to generate a 3D object model 20.

With further reference to FIGS. 1-5, the generative object design algorithm 14 includes a diffusion model 30 that is configured as a machine learning model. The generative object design algorithm 14 utilizes training data 32 to train the diffusion model 30. The diffusion model 30 includes a model trainer 34 that is configured to obtain or receive the training data 32 for training the diffusion model 30. As mentioned above, the diffusion model 30 is configured as a machine learning model 30, such that the model trainer 34 is configured to train the machine learning model 30 based on the training data 32. The model trainer 34 may receive the training data 32 from, for example, a training database 36 stored in the memory hardware 18. The training data 32 includes, but is not limited to, a plurality of stored 3D objects 32a and stored object slices 32b. The training data 32 may also include any type of data that the diffusion model 30 is trained to receive (text, images, audio, etc.). For example, the training data 32 may include text inputs 32c received by the diffusion model 30. The diffusion model 30 is trained to predict and generate a 2D object image 38 that may be utilized to, ultimately, generate the 3D object model 20.

The diffusion model 30 is provided with the training data 32 during training of the diffusion model 30. As mentioned above, the training data 32 may include stored 3D objects 32a. For example, the stored 3D objects 32a may include tens, hundreds, and/or thousands of object images stored in the memory hardware 18. The stored 3D objects 32a may correspond with, but are not limited to, wheel rims. For example, the wheel rims may be readily available images that can be uploaded and provided to the diffusion model 30 as training data 32. The stored object slices 32b are slices of the stored 3D objects 32a. For example, the stored object slices 32b may include a plurality of slices of the wheel rims of the stored 3D objects 32a. Each stored 3D object 32a may have corresponding stored object slices 32b. As a result, the training database 36 has a wide array of variation in the stored 3D objects 32a and stored object slices 32b that can be used to train the diffusion model 30.

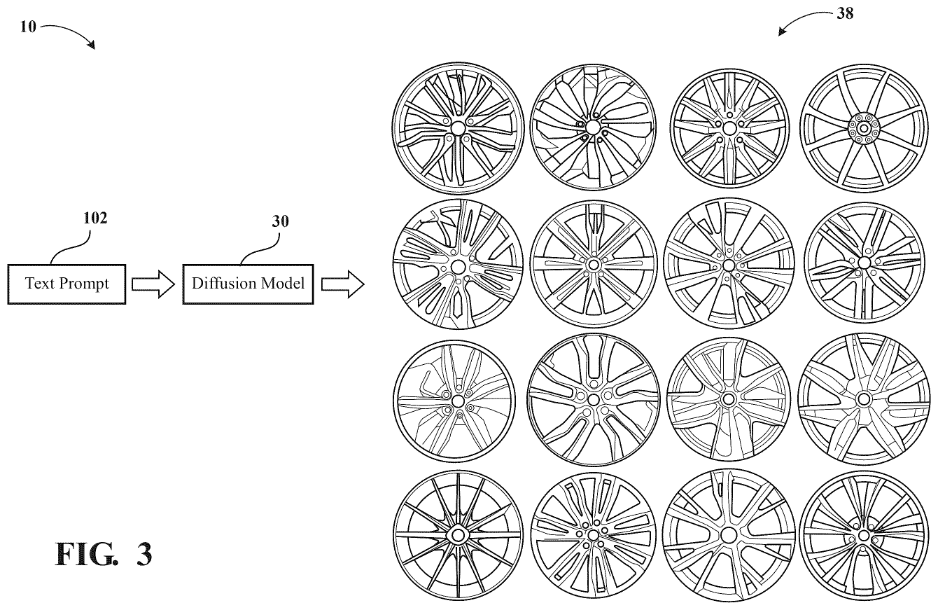

The stored object slices 32b may often contain approximately twelve (12) slices of the corresponding stored 3D object image 32a. The number of slices of the stored object slices 32b may vary depending on the complexity of the stored 3D object 32a. The use of approximately twelve (12) slices may advantageously train the diffusion model 30 on a wide array of object segmentations, which is advantageous for generating the 3D object model(s) 20. As described in more detail below, the diffusion model 30 may be utilized, at least in part, to assist in generating the 3D object model 20 in that the diffusion model 30 may be utilized to generate one or more 2D object images 38. For example, FIG. 3 illustrates the diffusion model 30 receiving a text prompt 32c and, in response, generating a plurality of 2D object images 38. The text prompt 32c may provide context to the diffusion model 30, such that the diffusion model 30 may utilize the context from the text prompt 32c to parse the training data 32 and generate the 2D object images 38 based on the training data 32. While the diffusion model 30 utilizes the training data 32 to inform the generated 2D object images 38, the 2D object images 38 are new designs independent of the training data 32.

For example, the diffusion model 30 utilizes the training data 32 to inform various 2D object images 38 in that the diffusion model 30 may pull various aspects from the different sets of training data 32 (i.e., the stored 3D objects 32a and stored object slices 32b). The diffusion model 30 may further utilize the text prompts 32c in combination with the pulled aspects from the training data 32 to generate the 2D object images 38. The text prompt 32c may indicate a user preference or other design context that may be requested by the user. In some instances, the text prompt 32c may include the images 102 that may be input at the interactive user interface 100. The diffusion model 30 may utilize the images 102 to select various combinations of the stored 3D object models 32a and the stored object slices 32b to generate the 2D object images 38.

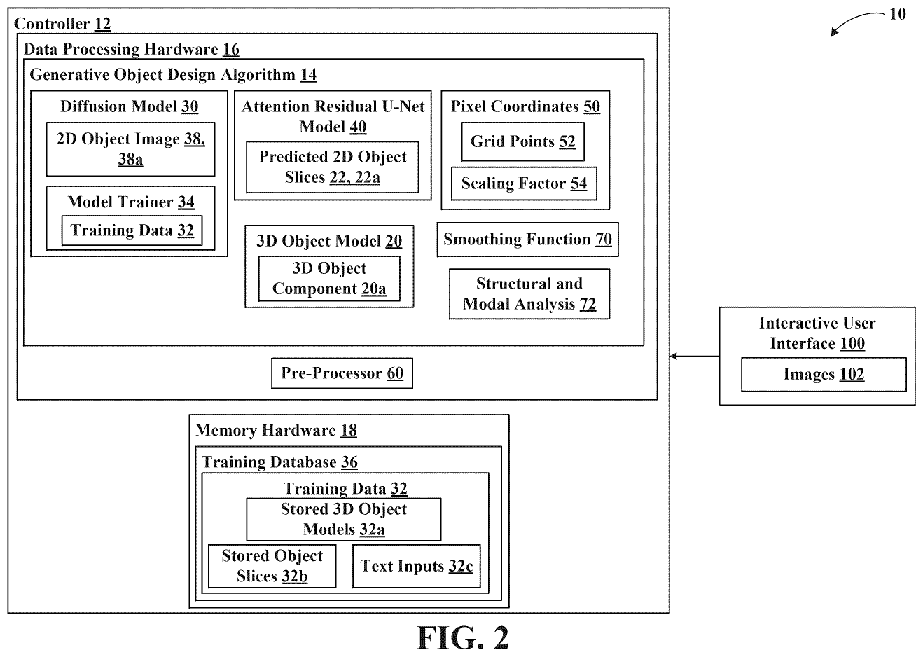

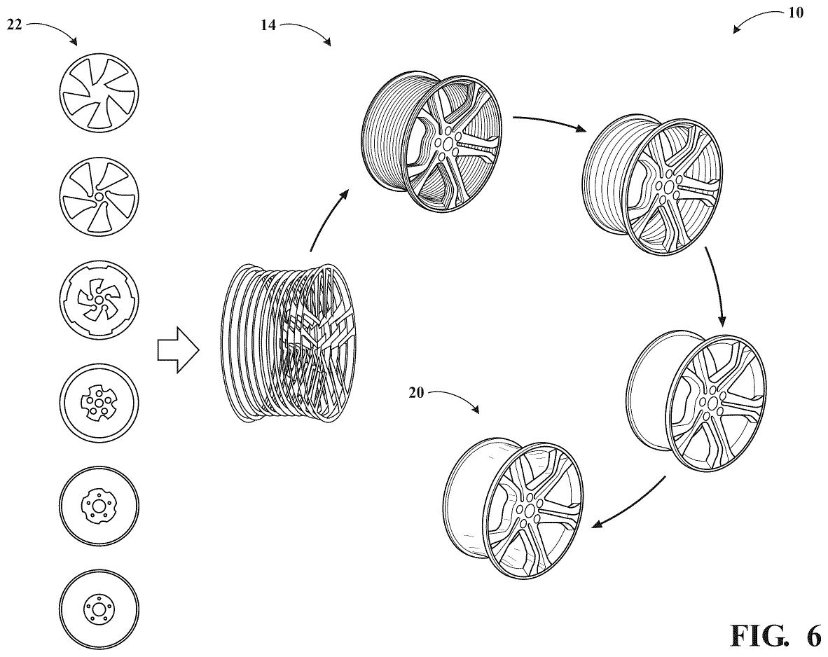

With reference to FIGS. 2-10, the 2D object images 38 are provided to an attention residual U-Net model 40 of the generative object design algorithm 14 in order to predict object slices 22 of the generated 2D object images 38. The attention residual U-Net model 40 receives one or more of the 2D object images 38 and is configured to predict the 2D object slices 22 for each 2D object image 38. For example, a user may select one of the 2D object images 38 from those generated by the diffusion model 30. Based on the user selection, the attention residual U-Net model 40 predicts and generates the 2D object slices 22. The attention residual U-Net model 40 cooperates with the diffusion model 30 as part of the generative object design algorithm 14 to predict the 2D object slices 22. For example, the attention residual U-Net model 40 may have similar access to the training database 36 to compare the generated 2D object image 38 with the stored 3D object models 32a and the stored image slices 32b. Based on the comparison, the attention residual U-Net model 40 may predict the individual object slices 22 of the selected 2D object image 38.

In some instances, the attention residual U-Net model 40 may receive the images 102 input at the interactive user interface 100 and may utilize the images 102 to inform the predicted 2D object slices 22. The predicted 2D object slices 22 may be presented as a series of black and white and/or grey-scale images that illustrate the generated 2D object image 38 at each slice 22. The black and white predicted 2D object slices 22 may be utilized by the generative object design algorithm 14 to generate the 3D object design, as the contrast between the black and white may provide improved edge detection. As mentioned above, the predicted 2D object slices 22 may be saved in the memory hardware 18 and/or may be stored locally by the user.

With further reference to FIGS. 2-10, the generative object design algorithm 14 may extract pixel coordinates 50 from the predicted 2D object slices 22. The pixel coordinates 50 correspond to an object of the predicted 2D object slices 22, such that the generative object design algorithm 14 may disregard pixels that may not correspond to the object of the predicted 2D object slices 22. The generative object design algorithm 14 utilizes the pixel coordinates 50 to create a corresponding grid point 52 for each valid pixel coordinate 50. The generative object design algorithm 14 may also apply a scaling factor 54 to each of the 2D object slices 22 to ensure that, when stacked, the 2D object slices 22 accurately reconstruct the object. The generative object design algorithm 14 communicates the grid points 52 with a pre-processor 60 of the data processing hardware 16 for further processing.

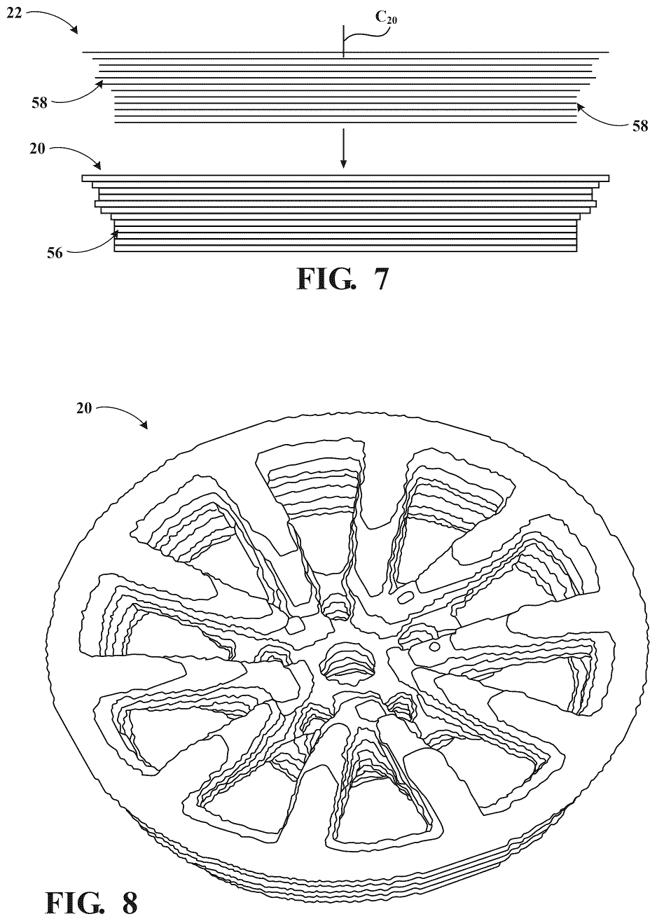

The grid points 52 capture features of the object. For example, if the object is a wheel, then the features may include, but are not limited to, rim, spokes, a center bore region, lug nut holes, and an outer lip. FIG. 8 illustrates an example of a 3D object model 20 (i.e., wheel) after the pre-processor 60 has refined the grid points 52. FIG. 7 illustrates the refinement of the grid points 52. For example, the grid points 52 from each slice 22 are wrapped using solid hexahedral elements to form a mesh 56 for each slice 22. Bottom grid points 52 of each slice 22 are extruded along an object centerline C20 to fill in voids 58 defined between each slice 22. For example, the mesh 56 filled the voids 58 to provide an improved resolution of the object model 20 while capturing the details of the object model 20.

The predicted 2D object slices 22 are thus combined via the generative object design algorithm 14 as a result of the refined grid points 52 and meshed object model 20 from the pre-processor 60. The combined predicted 2D object slices 22 result in the 3D object model 20. Once the 3D object model 20 is meshed and generated, the generative object design algorithm 14 may execute a smoothing function 70 that is configured to eliminate roughness and steps from the course construction of the 3D object model 20 from the predicted 2D object slices 22. Once smoothed, the generative object design algorithm 14 executes a structural and modal analysis 72 on the 3D object design 20. The structural and modal analysis 72 is utilized to apply loads and constraints on the 3D object model 20 to evaluate the practicality of the 3D object model 20.

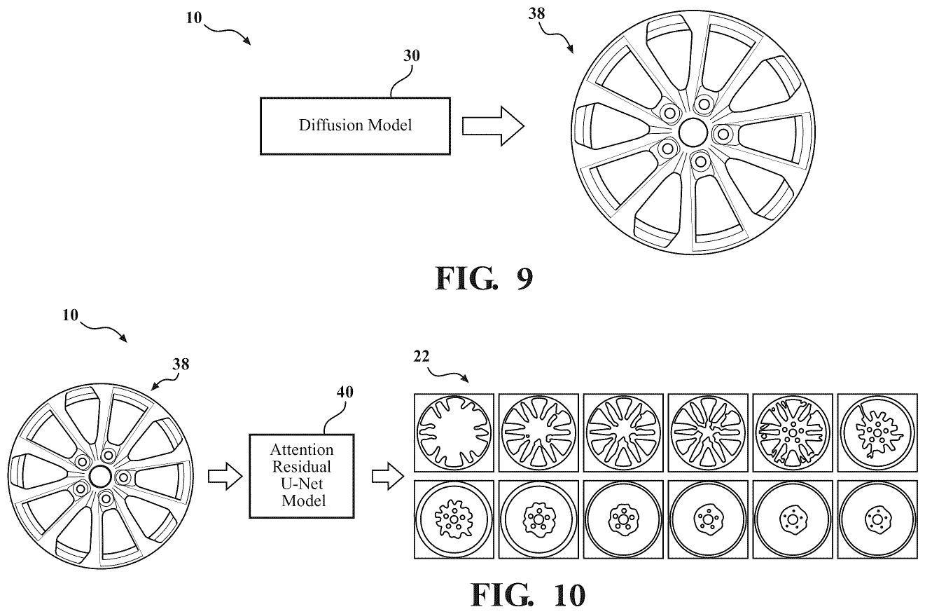

The diffusion model 30 is utilized to generate the 2D object image 38. For example, FIG. 9 illustrates the output of the 2D object image 38 after execution of the diffusion model 30. The 2D object image 38 may then be input into the attention residual U-Net model 40 to output the predicted 2D object slices 22. The 2D object slices 22 are projected slices based on the generated 2D object image 38. For example, FIG. 10 illustrates the output of the 2D object slices 22 as generated by the attention residual U-Net model 40.

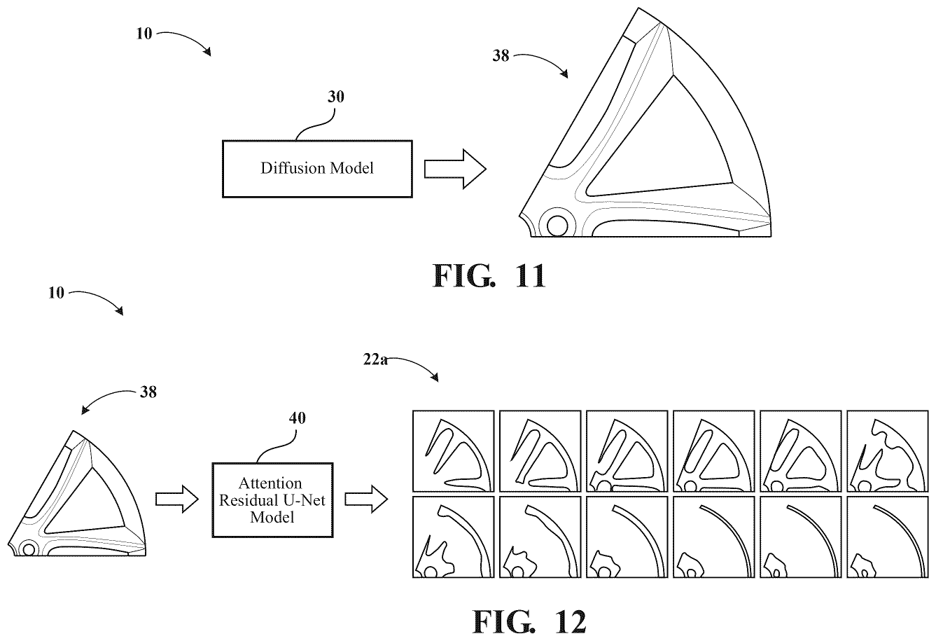

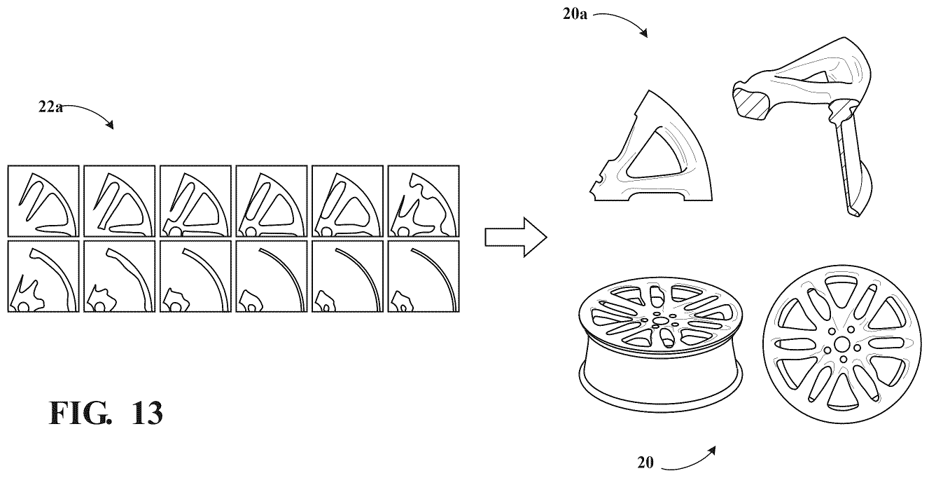

With specific reference to FIGS. 2 and 11-13, the generative object design algorithm 14 may be utilized to generate a singular 3D object component 20a of a 3D object model 20. For example, FIGS. 11-13 illustrate the use of the generative object design algorithm 14 to generate a singular spoke 20a of a wheel model 20. The generative object design algorithm 14 utilizes a similar process described above. The generative object design algorithm 14 may execute the diffusion model 30 to generate the 2D object image 38a. The diffusion model 30 still utilizes the training database 36 to train and generate the 2D object image 38a, regardless of whether the diffusion model 30 is being used to ultimately generate a singular 3D object component 20a or an entire 3D object model 20.

Once the 2D object image(s) 38a is generated, the generative object design algorithm 14 executes the attention residual U-Net model 40. The attention residual U-Net model 40 predicts and generates the 2D object slices 22a based on the generated 2D object image 38a from the diffusion model 30. In the illustrated example (FIG. 11), the 2D object slices 22a capture individual components 20a of the object model 20. The generative object design algorithm 14 combines the 2D object slices 22a into the 3D object component 20a. The generative object design algorithm 14 extracts the pixel coordinates 50 from the slices 22a and creates the corresponding grid points 52. The grid points 52 are communicated with the pre-processor 60 in a similar process described above with respect to FIGS. 2-10. The generative object design algorithm 14 may subsequently form the mesh 56 for each of the slices 22a based on the grid points 52 to generate the 3D object component 20a.

The generative object design algorithm 14 may then execute the smoothing function 70 and run the structural and modal analysis 72 on the 3D object component 20a. The generative object design algorithm 14 may also utilize the 3D object component 20a to extrapolate and form the entirety of the 3D object model 20. For example, FIG. 12 illustrates the generative object design algorithm 14 generating the 3D object model 20 from the 3D object component 20a.

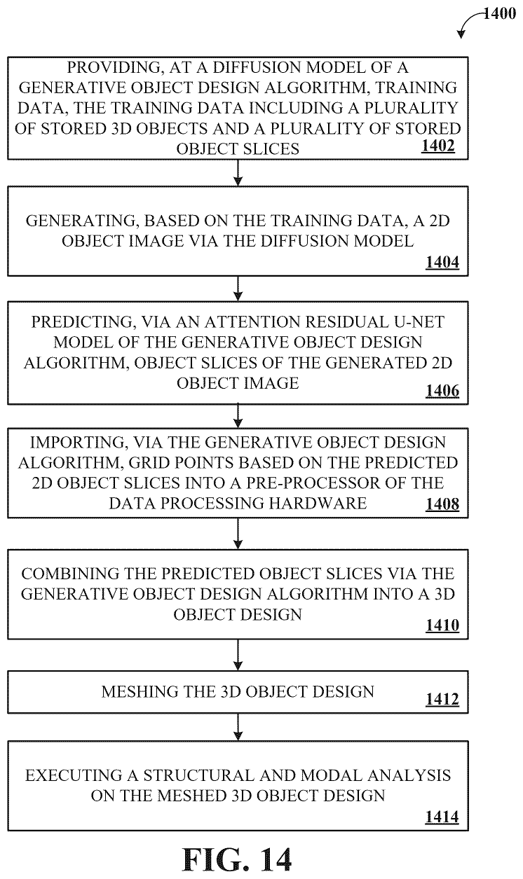

Referring to FIG. 14, an example method 1400 of operation of the generative object design system 10 is illustrated. At 1402, a diffusion model 30 of a generative object design algorithm 14 is provided with training data 32. The training data 32 includes a plurality of stored three-dimensional (3D) objects 32a and a plurality of stored object slices 32b. The diffusion model 30 generates, at 1404, based on the training data 32, a two-dimensional (2D) object image 38. An attention residual U-Net model 40 of the generative object design algorithm 14 predicts, at 1406, object slices 22 of the generated 2D object image 38. At 1408, grid points 52 are imported via the generative object design algorithm 14 into a pre-processor 60 of the data processing hardware 16 based on the predicted 2D object slices 22. The generative object design algorithm 14 combines, at 1410 the predicted object slices 22 into a 3D object model 20. The generative object design algorithm 14 meshes, at 1412, the 3D object model 20 and executes, at 1414, a structural and modal analysis 72 on the meshed 3D object model 20.

A number of implementations have been described. Nevertheless, it will be understood that various modifications may be made without departing from the spirit and scope of the disclosure. Accordingly, other implementations are within the scope of the following claims.

The foregoing description has been provided for purposes of illustration and description. It is not intended to be exhaustive or to limit the disclosure. Individual elements or features of a particular configuration are generally not limited to that particular configuration, but, where applicable, are interchangeable and can be used in a selected configuration, even if not specifically shown or described. The same may also be varied in many ways. Such variations are not to be regarded as a departure from the disclosure, and all such modifications are intended to be included within the scope of the disclosure.

What is claimed is:

1. A computer-implemented method when executed by data processing hardware causes the data processing hardware to perform operations comprising:
providing, at a diffusion model of a generative object design algorithm, training data, the training data including a plurality of stored three-dimensional (3D) objects and a plurality of stored object slices;
generating, based on the training data, a two-dimensional (2D) object image via the diffusion model;
predicting, via an attention residual U-Net model of the generative object design algorithm, 2D object slices of the generated 2D object image; and
combining the predicted object slices via the generative object design algorithm into a 3D object design.

2. The method of claim 1, further including generating, via the generative object design algorithm, a 3D object component and extrapolating the 3D object design from the generated 3D object component.

3. The method of claim 1, wherein providing the training data includes tuning the diffusion model based on the training data, the diffusion model being a machine learning model.

4. The method of claim 1, wherein predicting the 2D object slices includes generating at least twelve object slices.

5. The method of claim 1, further including importing via the generative object design algorithm, grid points based on the predicted 2D object slices into a pre-processor of the data processing hardware.

6. The method of claim 5, wherein combining the predicted 2D object slices includes refining the imported grid points.

7. The method of claim 6, further including extruding bottom grid points along each predicted 2D object slice via the generative object design algorithm.

8. The method of claim 7, further including meshing the 3D object design.

9. The method of claim 8, further including executing a structural and modal analysis on the meshed 3D object design.

10. A generative three-dimensional (3D) object design system comprising:
data processing hardware; and
memory hardware in communication with the data processing hardware, the memory hardware storing instructions that when executed on the data processing hardware cause the data processing hardware to perform operations comprising:
providing, at a diffusion model of a generative object design algorithm, training data, the training data including a plurality of stored three-dimensional (3D) objects and a plurality of stored object slices;
generating, based on the training data, a two-dimensional (2D) object image via the diffusion model;
predicting, via an attention residual U-Net model of the generative object design algorithm, object slices of the generated 2D object image; and
combining the predicted object slices via the generative object design algorithm into a 3D object design.

11. The generative 3D object design system of claim 10, wherein the stored 3D objects include wheel rims.

12. The generative 3D object design system of claim 10, wherein providing the training data includes tuning the diffusion model based on the training data, the diffusion model being a machine learning model.

13. The generative 3D object design system of claim 10, wherein predicting the 2D object slices includes generating at least twelve object slices.

14. The generative 3D object design system of claim 10, further including importing via the generative object design algorithm, grid points based on the predicted 2D object slices into a pre-processor of the data processing hardware.

15. The generative 3D object design system of claim 14, wherein combining the predicted 2D object slices includes refining the imported grid points.

16. The generative 3D object design system of claim 15, further including extruding bottom grid points along each predicted 2D object slice via the generative object design algorithm.

17. The generative 3D object design system of claim 16, further including meshing the 3D object design.

18. The generative 3D object design system of claim 17, further including executing a structural and modal analysis on the meshed 3D object design.

19. A generative three-dimensional (3D) object design system comprising:
data processing hardware; and
memory hardware in communication with the data processing hardware, the memory hardware storing instructions that when executed on the data processing hardware cause the data processing hardware to perform operations comprising:
providing, at a diffusion model of a generative object design algorithm, training data, the training data including a plurality of stored three-dimensional (3D) objects and a plurality of stored object slices;
generating, based on the training data, a two-dimensional (2D) object image via the diffusion model;
predicting, via an attention residual U-Net model of the generative object design algorithm, object slices of the generated 2D object image;
importing via the generative object design algorithm, grid points based on the predicted 2D object slices into a pre-processor of the data processing hardware;
combining the predicted object slices via the generative object design algorithm into a 3D object design;
meshing the 3D object design; and
executing a structural and modal analysis on the meshed 3D object design.

20. The generative 3D object design system of claim 19, further including generating, via the generative object design algorithm, a 3D object component and extrapolating the 3D object design from the generated 3D object component.
